(19) United States
(12) Patent Application Publication
(10) Pub. No.: US 2007/0158768 A1
(43) Pub. Date: Jul. 12, 2007

(54) Electrical contacts formed of carbon nanotubes

(75) Inventors: Jorg Pilchowski, Mercer Island, WA (US); George D. Skidmore, Richardson, TX (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc., Morristown, NJ (US)

(21) Appl. No.: 11/326,944

(22) Filed: Jan. 6, 2006

(51) Int. Cl. H01L 29/84; H01L 21/00

(52) U.S. Cl. 257/415; 438/50; 257/E29.324

(57) ABSTRACT

An apparatus and method for a micromachined mechanical switch device having first and second cooperating electrical switch contacts formed by respective first and second patterns of robust carbon nanotube thin film structures for forming intermittent electrical contact between the first and second conductors in response to the applied force urging the first and second cooperating patterns of carbon nanotube thin film structures together into momentary or substantially permanent physical contact.

### FIELD OF THE INVENTION

The present invention relates to micromachined mechanical switch devices and methods, and in particular to micromachined mechanical switch devices having electrical contacts formed of carbon nanotubes.

### BACKGROUND OF THE INVENTION

Electrical contacts in micromachined mechanical switches, e.g., RF switches, thermal switches, etc., are generally well-known to suffer from problems of long-term reliability. Typically, switch contacts are formed of thin film metal, e.g., gold, platinum, aluminum, nickel, and metal alloys such as gold alloys, platinum alloys, and nickel alloys. These thin film metal or metal alloy contacts are subject to the wear and tear of repeated make and break of the associated circuit, in-operation stiction, and contact welding, to name a few of the long-term reliability problems. In many applications, the designer must compromise electrical properties of the contacts to obtain desirable mechanical properties in order to achieve a desired reliability goal.

Thus, electrical contacts having both uncompromised electrical properties as well as highly reliable mechanical properties are desirable for micromachined mechanical switches.

### SUMMARY OF THE INVENTION

The present invention overcomes the long-term reliability and electrical property limitations of the thin film metal or metal alloy contacts known in the prior art by providing electrical contacts having both uncompromised electrical properties as well as highly reliable mechanical properties that are desirable for micromachined mechanical switches. Such material properties are provided in the invention by micromachined mechanical switches fabricated using carbon nanotubes. Carbon nanotubes are cylindrical carbon molecules that exhibit extraordinary strength, unique electrical properties, and efficient heat conductivity.

A nanotube is a member of the fullerene structural family with a cylindrical shape. There are two main types of nanotubes: single-walled nanotubes (SWNTs) and multi-walled nanotubes (MWNTs). Most SWNTs have diameters in the order of one nanometer, and a tube length many thousands of times larger. A conceptualized image of a SWNT is derived by wrapping a one-atom-thick layer of graphite (also called graphene) into a seamless cylinder. The way in which the graphene sheet is wrapped is represented by a pair of indices (n,m) commonly called the chiral vector. The indices n and m are integer numbers that denote the number of unit vectors along two directions in the honeycomb lattice of graphene, e.g., around the circumference of the tube, and along the tube's rotational axis. The values of the chiral vector greatly affect the electrical properties of carbon nanotubes. For a given (n,m) nanotube, if 2n+m=3r, where r is an integer, then the nanotube is metallic, otherwise the nanotube is a semiconductor. In theory, metallic nanotubes can conduct electrical currents with an electrical current density of more than 1,000 times higher than metals.

The present invention is an apparatus and method for a micromachined mechanical switch device having first and second electrical conductors spaced apart by any suitable solid, liquid or gas insulator. The first and second electrical conductors are formed with respective first and second opposing substantially planar electrically conductive contact surfaces. The first electrical conductor is structured to be movable relative to the second electrical conductor in response to an applied force for urging the first electrically conductive contact surface toward the second electrically conductive contact surface.

First and second cooperating electrical switch contacts are formed on the respective first and second opposing electrically conductive contact surfaces by respective first and second patterns of robust carbon nanotube thin film structures that are adhered to the respective first and second electrically conductive contact surfaces for forming intermittent electrical contact between the first and second conductors in response to the applied force urging the first and second cooperating patterns of carbon nanotube thin film structures together into momentary or substantially permanent physical contact.

Optionally, the first and second carbon nanotube thin film structures are formed by first and second patterns of a patterning material combined with quantities of carbon nanotubes, wherein the patterning material is selected from (a) carbon-dissolving materials, (b) carbide-forming materials, and (c) metals having a low melting point of about 700 degrees C. or less.

The first and second patterns of patterning material are deposited onto the respective first and electrically second conductive contact surfaces, and the carbon nanotubes are coupled thereto. A first quantity of the carbon nanotubes are coupled to the first pattern of patterning material at a surface thereof that is facing away from the first conductive contact surface of the corresponding first conductor and toward the opposing second conductor. A second quantity of the carbon nanotubes are coupled to the second pattern of patterning material at a surface thereof that is facing away from the second conductive contact surface of the corresponding second conductor and toward the opposing first conductor.

Alternatively, the patterning of electrical contacts with carbon nanotubes is achieved by local deposition of carbon nanotubes, e.g., through a shadow mask, in the contact area, or by applying a lift-off process.

Optionally, the first and second adherent carbon nanotube thin film structures are formed either (1) during formation of the carbon nanotubes, referred to as “in situ,” or (2) by treatment of pre-formed carbon nanotubes, referred to as “ex situ.”

The invention also provides methods of accomplishing the same.

### BRIEF DESCRIPTION OF THE DRAWINGS

The foregoing aspects and many of the attendant advantages of this invention will become more readily appreciated as the invention becomes better understood by reference to the following detailed description, when taken in conjunction with the accompanying drawings, wherein:

FIGS. 1A-1D illustrate the process of U.S. Pat. No. 6,277,318;

FIGS. 2A and 2B illustrate a process of the invention for local deposition of carbon nanotubes;

FIGS. 3A-3D illustrate a liftoff process of the invention for patterning contacts with carbon nanotubes;

FIG. 4 illustrates a micromachined mechanical switch device of the present invention having opposing first and second electrical conductors having cooperating electrical contacts formed by patterns of carbon nanotubes;

FIG. 5 illustrates an alternative embodiment of the invention wherein the opposing first and second electrical conductors are alternatively formed of insulators having electrically conductive electrode layers applied to their respective surfaces;

FIG. 6 illustrates the micromachined mechanical switch device of the present invention as a force sensor for sensing the applied force as an input acceleration force, i.e., an accelerometer, or as an input pressure force, i.e., a pressure sensor; and

FIG. 7 illustrates the micromachined mechanical switch device of the present invention as a thermal sensor responsive to a change in a sensed ambient temperature.

### DETAILED DESCRIPTION OF PREFERRED EMBODIMENT

In the Figures, like numerals indicate like elements.

The Figures illustrate the method of the present invention for a micromachined mechanical switch device having first and second cooperating electrical switch contacts formed by respective first and second patterns of robust carbon nanotube thin film structures for forming intermittent electrical contact between the first and second conductors in response to the applied force urging the first and second cooperating patterns of carbon nanotube thin film structures together into momentary or substantially permanent physical contact.

Optionally, the first and second carbon nanotube thin film structures are formed by first and second patterns of a patterning material combined with quantities of carbon nanotubes, wherein the patterning material is selected from (a) carbon-dissolving materials, (b) carbide-forming materials, and (c) metals having a low melting point of about 700 degrees C. or less.

Optionally, the first and second carbon nanotube thin film structures are formed by locally depositing carbon nanotubes in the contact areas, e.g., through a shadow mask.

Optionally, the first and second carbon nanotube thin film structures are formed by patterning a sacrificial material such that the contact areas are free of sacrificial material. After blanket deposition of the carbon nanotubes, the sacrificial material is removed, e.g., dissolved, resulting in the removal of all carbon nanotubes layered above it, leaving carbon nanotubes only in the contact areas.

Optionally, the first and second adherent carbon nanotube thin film structures are formed either (1) during formation of the carbon nanotubes, referred to as “in situ,” or (2) by treatment of pre-formed carbon nanotubes, referred to as “ex situ.”

Carbon nanotubes are generally well-known. As taught by Bower, et al. in U.S. Pat. No. 6,277,318, “Method for fabrication of patterned carbon nanotube films,” Aug. 21, 2001, the complete disclosure of which is incorporated herein by reference, carbon nanotubes have interesting electronic properties and offer potential for use in electronic devices and in interconnect applications.

As taught by Bower, et al. in U.S. Pat. No. 6,630,772, “Device comprising carbon nanotube field emitter structure and process for forming device,” Oct. 7, 2003, the complete disclosure of which is incorporated herein by reference, carbon nanotubes feature geometric characteristics of high aspect ratio, generally >1,000, and atomically sharp tips having tip radii of curvature of about 10 nm that, coupled with the relatively high mechanical strength and chemical stability of the nanotubes 14, make them ideal candidates for electron field emitters.

To realize these potential applications, in U.S. Pat. No. 6,277,318 Bower, et al. taught a method for processing nanotubes into useful forms such as thin films, and patterned thin films.

Previously, carbon nanotubes were being produced by a variety of different techniques such as arc-discharge, laser ablation and chemical vapor deposition (CVD). The as-deposited material, however, was usually in the form of loose powders, porous mats, or films with poor adhesion. These forms of nanotubes did not lend themselves to convenient preparation of robust adherent nanotube thin film structures.

U.S. Pat. No. 6,277,318 taught a method for fabricating adherent, patterned carbon nanotube films having an adhesion strength of the film exceeds scale 2A or 2B according to ASTM tape testing method D3359-97. The resultant adherent, patterned nanotube film is claimed to have a thickness of generally 100 to 1000 nm.

According to U.S. Pat. No. 6,277,318, a substrate is patterned with a carbide-forming material, a carbon-dissolving material, or a low melting point metal of about 700 degree C. or less. Carbon nanotubes are then deposited onto the patterned substrate, e.g., by spraying or suspension casting. The substrate is then annealed, typically in vacuum, at a temperature dependent on the particular patterning material, e.g., a temperature at which carbide formation occurs, at which carbon dissolution occurs, or at which the low melting point metal melts. The annealing provides an adherent nanotube film over the patterned areas, while the nanotubes deposited onto the non-patterned areas are easily removed, e.g., by blowing, rubbing, brushing, or ultrasonication in a solvent such as methanol. Bower, et al. claim that the process of U.S. Pat. No. 6,277,318 provides an adherent nanotube film in a desired pattern. The patterned films are expected to be useful for a variety of devices, including vacuum microelectronic devices such as flat panel displays, as well as other structures, e.g., nanotube interconnects.

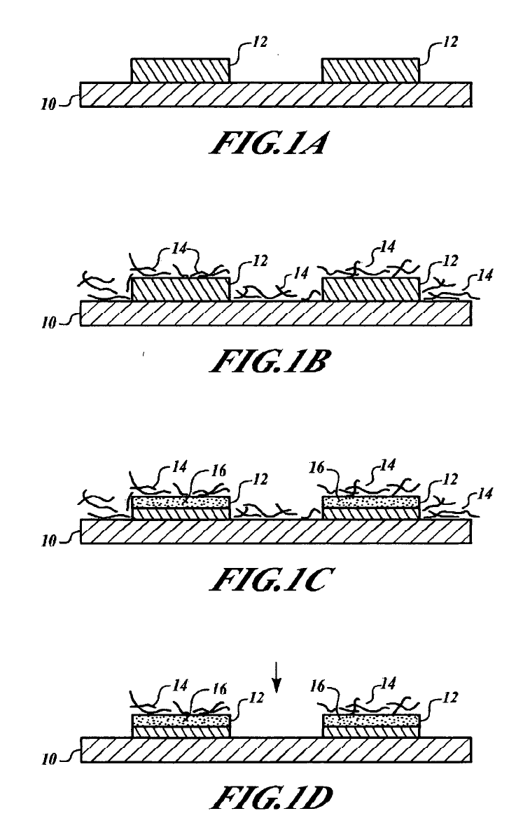

FIGS. 1A-1D illustrate the process of U.S. Pat. No. 6,277,318 that is claimed to provide an adherent nanotube film in a desired pattern and having a thickness of generally 100 to 1000 nm. A flat substrate 10 is first provided that is substantially non-reactive with carbon, e.g., neither carbide-forming nor carbon-dissolving, and has a relatively high melting point, typically at least 1000 degrees C. Examples include SiO₂ (including Si wafers having an oxidized surface layer), indium tin oxide (ITO), Al₂O₃, Cu, and Pt.

In FIG. 1A, a patterning material 12 is deposited onto the substrate 10 in a pattern desired for the nanotube film. The patterning material 12 is selected from (a) carbon-dissolving materials, (b) carbide-forming materials, and (c) metals having a low melting point of about 700 degrees C. or less. Carbon-dissolving materials are known in the art and include elements such as Ni, Fe, Co, and Mn. Carbide-forming elements are similarly known in the art and include elements such as Si, Mo, Ti, Ta, W, Nb, Zr, V, Cr, and Hf. Typical low melting point metals include Al, Sn, Cd, Zn, and Bi. The thickness of the patterning material 12 is typically 10 to 100 nm. The patterning material is deposited by any suitable technique, e.g., sputtering, evaporation, or chemical vapor deposition. Conventional lithographic processes are generally used to provide the desired pattern.

In FIG. 1B, carbon nanotubes 14 are then deposited onto the patterned substrate 10. The nanotubes are typically deposited by suspension casting or spray coating. Suspensions of nanotubes 14 can be made using various polymers, including those that provide non-covalent functionalization. Some of these non-covalent functionalization polymers and methods are described by Chen et. al. in U.S. Pat. No. 6,905,667, the complete disclosure of which is incorporated herein by reference. Suspension casting may be performed by placing the substrate 10 into a nanotube suspension made up of nanotubes 14 and a solvent such as methanol, and allowing the solvent to evaporate. Spray coating is performed by spraying such a suspension onto the heated substrate using an air gun, and allowing the solvent to evaporate. Both methods are claimed to provide relatively uniform thin films of randomly oriented nanotubes.

In FIG. 1C, the substrate 10 is then annealed, generally in vacuum of 10⁻⁶ torr or less. The temperature of the anneal is selected based on the patterning material 12. The temperature being chosen to promote carbon dissolution, carbide formation, or melting of the patterning material 12. The anneal is generally performed 30 minutes to 24 hours, depending on the particular patterning material. By inducing carbon dissolution, carbide formation or melting at the areas where the nanotubes 14 contact the patterning material 12, an area 16 of enhanced adherence between the nanotubes 14 and patterning material 12 is created. Specifically, for carbide-forming material, a carbide is formed by reaction of the material and at least a portion of the nanotubes. For carbon-dissolving material, a metal-carbon solid solution is formed by reaction of the material and at least a portion of the nanotubes. And for low melting point metals, at least a portion of the nanotubes become physically embedded in a molten metal layer and then held in place upon cooling.

In FIG. 1D, the nanotubes 14 deposited directly on the substrate 10 material are removed after annealing. Because the nanotubes 14 have relatively poor adherence to the substrate 10 material, removal is relatively easy. Removal is capable of being performed by blowing, rubbing, or brushing the surface of the substrate 10, or by ultrasonication in a solvent such as methanol. It is possible to combine these techniques. Ultrasonication, when performed without any other removal technique, is generally performed for 0.5 to 24 hours.

Thickness of the resultant adherent, patterned nanotube film is claimed to be generally 100 to 1000 nm. Adhesion strength is claimed to be sufficient to exceed the 2A or 2B scale in the ASTM tape test D3359-97.

As taught by Bower, et al. in both U.S. Pat. No. 6,277,318 and U.S. Pat. No. 6,630,772, the geometric characteristics of carbon nanotubes, i.e., high aspect ratio and atomically sharp tip radii, coupled with the relatively high mechanical strength and chemical stability of the nanotubes 14, make them ideal candidates for electron field emitters.

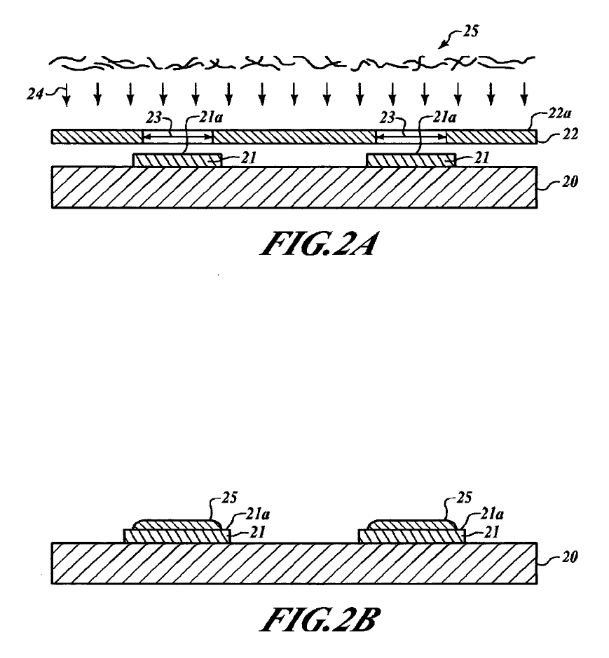

FIGS. 2A and 2B illustrate the process of locally depositing carbon nanotubes through a shadow mask. As illustrated in FIG. 2A, a flat substrate 20 is first provided that has areas of electrical contacts 21 which provide adherence to carbon nanotubes. Examples of the substrate 20 include SiO₂ (including silicon wafers having an oxidized surface layer), indium tin oxide (ITO), and Al₂O₃. The material of electrical contacts 21 has an activated surface 21a to which carbon nanotubes adhere during deposition or after post-deposition processing.

A flat shadow mask 22 is brought into proximity or contact with the substrate 20. The shadow mask 22 has patterns of openings or windows 23 substantially similar or identical to the pattern of contact areas 21. The shadow mask 22 is aligned to the substrate 20 such that the openings 23 match the contact areas 21. Examples of materials for the shadow mask are silicon, silicon having an silicon oxide or silicon nitride surface layer, or various metals and metal alloys.

The aligned stack of the substrate 20 and the shadow mask 22 is subjected to blanket deposition (indicated generally by arrows 24) of carbon nanotubes 25. Deposition 24 takes place at a surface 22a of the shadow mask 22 facing away from the substrate 20 and on the substrate in the contact areas 21 at the locations where the shadow mask 22 has openings 23. The mechanism of deposition 24 is not limited to, but may include spraying, suspension casting, arc-discharge, laser ablation and chemical vapor deposition. Adherent carbon nanotubes 25 are formed in-situ during deposition 24 or ex-situ using post-processing after deposition.

As illustrated in FIG. 2B, after deposition 24, the shadow mask 22 is removed from the substrate 20. If desired, adhesion of the local layer of carbon nanotubes 25 to the contact areas 21 is improved during post-processing. Alternatively, post-processing to improve adherence of the carbon nanotubes 25 is performed with the shadow mask 22 still in place, and the shadow mask 22 is removed from its position of contact or proximity with the substrate 20 after such post-processing . The result is a layer of carbon nanotubes 25 firmly adhered in the contact areas 21 of the substrate 20.

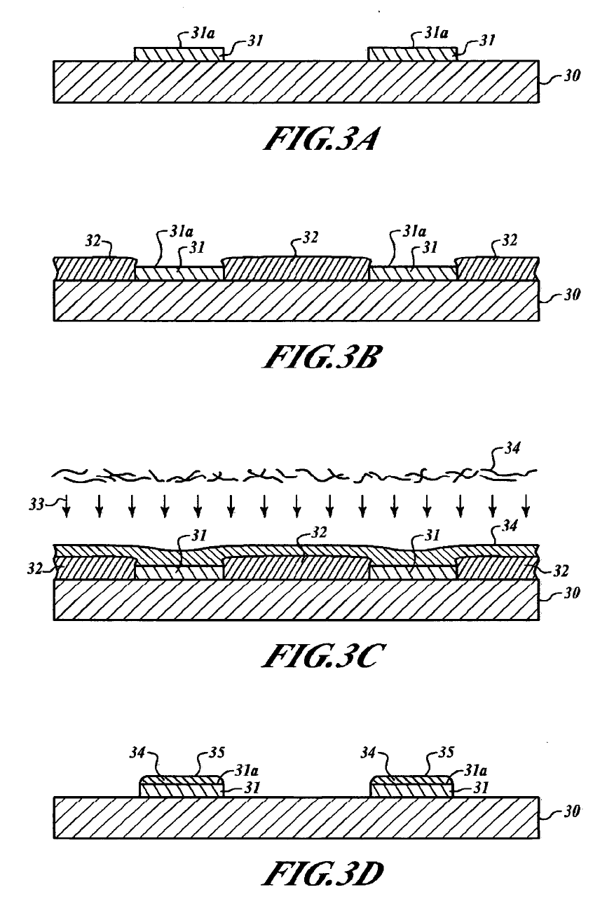

FIGS. 3A-3D illustrate the liftoff process for patterning contacts with carbon nanotubes. As illustrated in FIG. 3A, a flat substrate 30 is first provided that has areas of electrical contacts 31 which provide adherence to carbon nanotubes. Examples of the substrate 30 include SiO2 (including silicon wafers having an oxidized surface layer), indium tin oxide (ITO), and Al2O3. The material of electrical contacts 31 has an activated surface 31a to which carbon nanotubes adhere during deposition or after post-deposition processing.

As illustrated in FIG. 3B, a layer of sacrificial material 32 is deposited and patterned on the substrate 30 such that the activated surfaces 31a of the contact areas 31 are free of the sacrificial material 32. The sacrificial layer 32 is a material which can be removed selectively with respect to the material in the contact areas 31. Selective removal is accomplished either by chemical etching, or by dissolving the material in a solvent based solution. An example of the sacrificial material 32 which is selectively removed with respect to metals is photo resist. Photo resist is easily patterned using standard photolithographic techniques. The selection of a suitable sacrificial material 32 is also affected by process conditions, e.g., temperature, during in-situ or ex-situ formation of carbon nanotubes.

In FIG. 3C, the prepared substrate 30 is then subjected to blanket carbon nanotube deposition (indicated generally by arrows 33), depositing a layer of carbon nanotubes 34. The mechanism of deposition is not limited to, but may include spraying, suspension casting, arc-discharge, laser ablation and chemical vapor deposition.

Adherent carbon nanotubes 34 are formed in-situ during deposition 33 or ex-situ using post-processing after deposition.

In FIG. 3D, the sacrificial layer 32 is removed using selective etching or dissolution in a solvent based solution. The removal of the sacrificial layer 32 also removes all carbon nanotubes deposited on top of the sacrificial layer 32. After removal of the sacrificial layer 32, a layer 35 of adherent carbon nanotubes 34 remains covering the surfaces 31a of the contact areas 31 of the substrate 30.

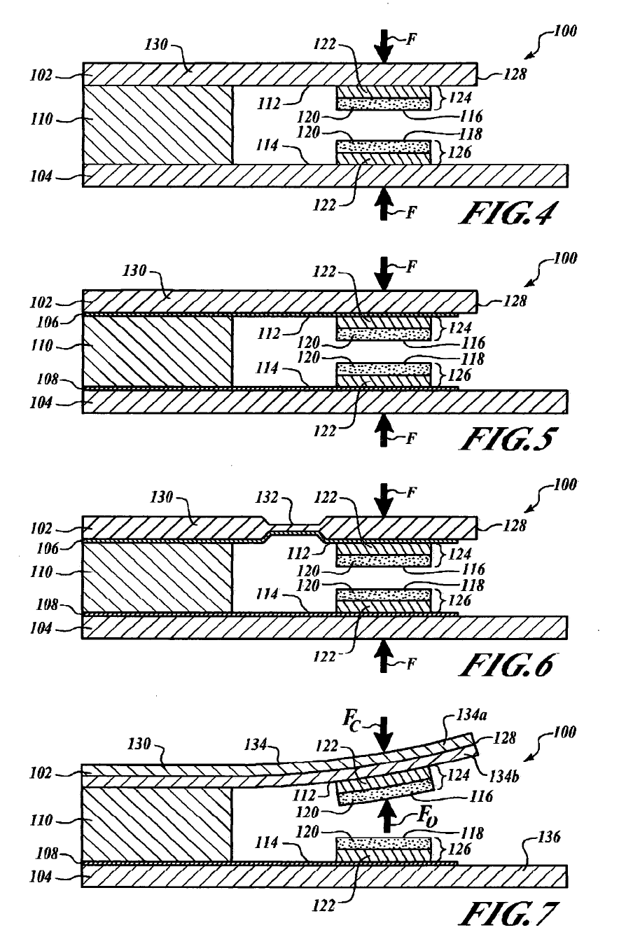

FIG. 4 illustrates a micromachined mechanical switch device 100 of the present invention having first and second electrical conductors 102, 104. According to one embodiment of the invention, the first and second electrical conductors 102, 104 are substrates that are substantially non-reactive with carbon and have relatively high melting points, typically at least 1000 degrees C. When formed as electrical conductors, the substrates 102, 104 are any of a metal, a semiconductor, or a conductive oxide, i.e., having a resistivity less than 10³ ohm-cm.

Alternatively, as illustrated in FIG. 5, the substrates 102, 104 are insulators having electrically conductive electrode layers 106, 108 applied to their respective surfaces. Substrate examples include Sio₂ (including Si wafers having an oxidized surface layer), indium tin oxide (ITO), and Al₂O₃.

The first and second electrical conductors 102, 104 are spaced apart by an electrical insulator 110. For example, the insulator 110 is an oxide or nitride layer between the substrates 102, 104. Alternatively, the insulator 110 is a non-conductive liquid or gas, such as air, an inert gas, or mixture of inert gasses, such as a conventional mixture of dry nitrogen and helium. The ideal insulator 110 is vacuum for some applications.

Each of the first and second substrates 102, 104 is formed with opposing substantially flat and planar electrically conductive contact surfaces 112, 114. When the substrates 102, 104 are metal, semiconductor or conductive oxide, the electrically conductive contact surfaces 112, 114 are surfaces of the respective electrical conductor substrates 102, 104. Alternatively, as illustrated in, when the substrates 102, 104 are insulators having conductive electrode layer 106, 108 applied to their surfaces, the electrically conductive contact surfaces 112, 114 are surfaces of the respective conductive layers 106, 108.

First and second cooperating electrical switch contacts 116, 118 are formed by first and second patterns of carbon nanotubes 120 that are substantially permanently coupled to the respective first and second electrically conductive contact surfaces 112, 114 of the respective substrates 102, 104.

The first and second cooperating electrical switch contacts 116, 118 are provided by adhering the first and second patterns of carbon nanotubes 120 to the electrically conductive contact surfaces 112, 114. By example and without limitation, the first and second patterns of carbon nanotubes 120 are adhered to the electrically conductive contact surfaces 112, 114 using the methods taught by Bower, et al. in one or both of U.S. Pat. No. 6,277,318 and U.S. Pat. No. 6,630,772, or another suitable method. For example, the first and second patterns of carbon nanotubes 120 are formed by large quantities of the carbon nanotubes 120 adhered to patterns of a patterning material 122 that is deposited onto the substrate contact surfaces 112, 114 in a pattern desired for the respective first and second cooperating electrical switch contacts 116, 118. As taught by Bower, et al. in one or both of U.S. Pat. No. 6,277,318 and U.S. Pat. No. 6,630,772, the patterning material 122 is selected from (a) carbon-dissolving materials, (b) carbide-forming materials, and (c) metals having a low melting point of about 700 degree C. or less. The carbon nanotubes 120 are then deposited onto the patterned substrate contact surfaces 112, 114, e.g., by spraying or suspension casting. The substrates 102, 104 are then annealed, typically in vacuum, at a temperature dependent on the particular patterning material, e.g., a temperature at which carbide formation occurs, at which carbon dissolution occurs, or at which the low melting point metal melts. Annealing promotes adherence of the nanotubes 120 to the patterning material 122. The annealing thereby provides the first and second cooperating electrical switch contacts 116, 118 as respective adherent carbon nanotube films 124, 126 formed of the carbon nanotubes 120 combined with the patterned material 122. The nanotubes 120 deposited onto the non-patterned areas are removed, e.g., by blowing, rubbing, brushing, or ultrasonication in a solvent such as methanol, leaving the respective adherent carbon nanotube films 124, 126 that form the first and second cooperating electrical switch contacts 116, 118.

Alternatively, the carbon nanotube films 124, 126 are patterned using either the method of deposition through a shadow mask explained above in FIGS. 2A and 2B, or liftoff patterning explained above in FIGS. 3A-3D.

As taught by Bower, et al. in one or both of U.S. Pat. No. 6,277,318 and U.S. Pat. No. 6,630,772, the adherent carbon nanotube film structures 124, 126 of the first and second cooperating electrical switch contacts 116, 118 are formed either (1) during formation of the nanotubes 120, referred to as “in situ,” or (2) by treatment of pre-formed nanotubes 120, referred to as “ex situ.” For either method, the carbon nanotubes 120 are optionally produced by any of a number of different techniques, including carbon-arc discharges, chemical vapor deposition via catalytic pyrolysis of hydrocarbons, laser ablation of catalytic metal-containing graphite target and condensed-phase electrolysis. Depending on the method of preparation and the specific process parameters, which largely control the degree of graphitization and the helicity and the diameter of the tubes, the nanotubes 120 are optionally produced primarily as multi-walled tubes, single-walled tubes, or bundles of single-walled tubes. Similarly, the tubes may adopt various shapes, such as straight, curved, chiral, achiral, and helix. The nanotubes 120 may be formed along with some amorphous carbon and catalyst particles intermixed therein, although the amorphous carbon and catalyst particles may be removed by etching in an oxygen plasma, which is selective to the amorphous carbon over the nanotubes, by heating at temperatures greater than 600 degree C. in air or under partial oxygen pressure, by etching in acid, or by filtration. The electrical and mechanical properties of the carbon nanotubes depend on the specific nanotube structure and are selected to satisfy the electrical contact properties desirable in the application, e.g., a Young's Modulus and electrical conductivity larger than conventional contact metals, such as gold, platinum and their alloys.

For in situ formation of an adherent nanotube film structures 124, 126, the material forming the first and second electrically conductive contact surfaces 112, 114, i.e., the substrates 102, 104 or conductive electrode layer 106, 108 applied to their surfaces, is selected to be generally reactive with carbon. Carbon-reactive materials include carbon-dissolving elements and carbide-forming elements. Carbon-dissolving materials are known in the art, and include elements such as Ni, Fe, Co, and Mn. Carbide-forming materials are similarly known, and include elements such as Si, Mo, Ti, Ta, W, Nb, Zr, V, Cr, and Hf. If the substrates 102, 104 are not carbon-reactive, or conductive electrode layers 106, 108 are applied to their surfaces are not carbon-reactive, a layer of a carbon-reactive material is deposited to form the contact surfaces 112, 114.

By example and without limitation, an initial layer of amorphous carbon is deposited to facilitate adhesion of the carbon nanotubes 120. A typical nanotube fabrication process produces at least 20 vol.% amorphous carbon, which intermixes with the nanotubes 120. Parameters of the nanotube fabrication process may be adjusted, such as by lowering the growth temperature, reducing the concentration of catalytic metals, adding an additional graphite target in a laser ablation method, or increasing the carbon concentration in the gas phase for chemical vapor deposition, to produce a greater concentration of amorphous carbon. Amorphous carbon does not exhibit the perfect atomic structure of nanotubes so that it more easily adheres to a variety of substrates, e.g., through dissolution or carbide formation. Once a thin amorphous carbon layer is deposited, the formation process is gradually adjusted to increase the percentage of nanotubes 120 being generated. The resulting thin film structures 124, 126 contain amorphous carbon and nanotubes, with the interfacial and intermixed amorphous carbon anchoring the nanotubes 120. The combined amorphous carbon/nanotube thin film structures 124, 126 generally have overall thicknesses of about 0.1 to about 100 micrometer.

In situ formation of the adherent carbon nanotube film structures 124, 126 is optionally performed by a laser ablation technique as known in the art wherein a target of graphite powder mixed with metal catalysts and graphite cement. A Nd:YAG pulsed laser is typically used to ablate the target. Each first and second substrates 102, 104 formed with respective electrically conductive contact surfaces 112, 114, as discussed herein, is co-located downstream of the target. When the target is ablated by the laser, a film of carbon nanotubes 120 is deposited onto the substrate contact surfaces 112, 114. As taught by Bower, et al. in U.S. Pat. No. 6,630,772, pre-deposition of amorphous carbon may be used to improve adhesion of the nanotubes 120, which may be accomplished by including a second target formed primarily from graphite for yielding the amorphous carbon. The extent of ablation of the first target vis-à-vis the second target is used to control the ratio of nanotubes and amorphous carbon deposited onto the substrate contact surfaces 112, 114.

In situ formation of the adherent carbon nanotube film structures 124, 126 is optionally performed by chemical vapor deposition inside a vacuum chamber. A reactive carbon-containing gas is directed into the chamber along with an inert or carrier gas. During deposition, the first and second substrates 102, 104 are heated. Carbon nanotubes 120 are nucleated by pre-coating the substrate contact surfaces 112, 114 with catalytic metals such as nickel, cobalt, ferrite, or alloys thereof Catalysts are alternatively provided through the gas phase by use of ferrocene or ferric acid. Where deposition of amorphous carbon is desired, the growth conditions are adjusted using known techniques to attain such amorphous carbon.

Thus, nanotubes 120 mixed with amorphous carbon are able to be deposited directly onto the contact surfaces 112, 114 as the adherent thin film structures 124, 126 having an adhesion strength reported to be at least 1.0 kpsi.

Alternatively, adherent nanotube thin film structures 124, 126 are fabricated ex situ using nanotubes 120 that are pre-formed by any known method such as discussed herein. With such an ex situ technique, the nanotube-containing product may be purified before the mixing to remove co-deposited amorphous carbon. Such purification is achieved by heating in air above 600 degree C., by using oxygen plasma to preferentially etch the amorphous carbon components of the nanotube thin film structures 124, 126, by acid etching, or by filtering the deposit.

In one ex situ embodiment, the adherent nanotube thin film structures 124, 126 are formed by mixing nanotube powder with a solvent, such as methanol, in an ultrasonic bath. The suspension or slurry is disposed onto the contact surfaces 112, 114 by techniques such as spinning or spraying. The contact surfaces 112, 114 are pre-coated with carbon-reactive or carbide-forming elements, such as those discussed herein. Alternatively, the contact surfaces 112, 114 are coated with a low melting point, <700 degree C., material such as aluminum. Subsequent heating then induces a reaction between the nanotubes 120 and carbon-reactive or carbide-forming elements, or induces melting of the low melting point material, such that the nanotubes 120 become anchored to the respective contact surfaces 112, 114.

Alternatively, nanotube powders are mixed with solvents and binders to form a solution or slurry. Optionally, the mixture also contains conductive particles such as elemental metals or alloys, e.g., solder, to further promote adhesion. The mixture is screen printed or dispersed, e.g., by spray or spin-on methods or electrophoresis, onto the contact surfaces 112, 114 to form the adherent nanotube thin film structures 124, 126. Annealing in either air, vacuum or inert atmosphere is then performed to drive out the solvent and activate the binder, resulting in the adherent nanotube thin film structures 124, 126 on respective contact surfaces 112, 114. Where solder particles are used, particularly solders having low melting temperatures of less than 200 degree C., e.g., Sn, In, Sn—In, Sn—Bi or Pb—Sn, the annealing temperature is sufficient to melt the solder, which enhances the adhesion of the nanotubes 120.

Alternatively, the nanotube powder is mixed with conductive polymers, e.g., silver-based polymers, and the mixture is applied to the contact surfaces 112, 114 by conventional methods such as screen printing, spray or spin-on methods, or electrophoresis, or by more simple mechanical methods, such as pressing, to form the adherent nanotube thin film structures 124, 126.

Metallic nanotubes, that is SWNT's with a chiral vector (n,m) where n=m, or MWNTs, are well suited for electrical switch contact applications because they exhibit good electrical conductivity combined with good mechanical strength to prevent contact abrasion.

Whether provided as the carbon nanotube thin film structures 124, 126 or other suitable carbon nanotubes, the first and second patterns of carbon nanotubes 120 form the cooperating electrical switch contacts 116, 118 on the spaced apart electrical conductor substrates 102, 104. The cooperating electrical switch contacts 116, 118 are operable for forming intermittent electrical contact when a force F is applied to one or both of the substrates 102, 104 for driving the cooperating electrical switch contacts 116, 118 together into momentary or substantially permanent physical contact.

FIG. 6 illustrates the micromachined mechanical switch device 100 of the present invention as a force sensor for sensing the applied force F as an input acceleration force, i.e., an accelerometer, or as an input pressure force, i.e., a pressure sensor. According to one embodiment of the invention, the micromachined mechanical switch device 100 includes by example and without limitation a pendulous proof mass 128 and a relatively stationary frame portion 130 optionally formed in one substrate 102 (or 104). The pendulous proof mass 128 is movably suspended from the relatively stationary frame 130 by one or more flexures 132 optionally also formed in the same substrate 102 (or 104).

One of the cooperating electrical switch contacts 116 (or 118) is formed on the relatively movable proof mass 128 opposite from the other cooperating electrical switch contacts 118 (or 116) with the two switch contacts 116, 118 being mutually electrically isolated, for example, by the insulator 110. The one or more flexures 132 permit the force F applied to the proof mass 128 to drive the electrical switch contacts 116 (or 118) thereon into physical contact with the other cooperating electrical switch contacts 118 (or 116) for making an electrical connection therebetween.

The substrates 102, 104 are optionally insulators, as illustrated, having the electrically conductive electrode layers 106, 108 applied to their respective surfaces. Alternatively, the substrate 102, 104 are electrical conductors formed of any of a metal, a semiconductor, or a conductive oxide, whereby the electrically conductive electrode layers 106, 108 eliminated.

FIG. 7 illustrates the micromachined mechanical switch device 100 of the present invention as a thermal sensor for sensing the applied force F as an input thermal force. According to one embodiment of the invention, the micromachined mechanical switch device 100 includes by example and without limitation one of the substrates 102 (or 104) formed as a relatively moveable thermally-responsive actuator 134 of a type that is generally well-known in the art. By example and without limitation, the thermally responsive actuator 134 consists of two layers, bonded to each other, with different thermal coefficients of expansion. By example and without limitation, the thermally-responsive actuator 134 is a snap-action bimetallic strip that inverts with a snap-action between two bi-stable oppositely concave and convex states as a function of a change in sensed temperature. The thermally-responsive actuator 134 is spaced away from a relatively stationary frame portion 136 formed of the other substrate 104 (or 102).

A portion 134a of the thermally-responsive actuator 134 is movable relative to another portion 134b thereof that is relatively stationary. In a first state, the bimetallic disc actuator 134 is convex relative to the relatively stationary frame portion 136 optionally formed in the other substrate 104 (or 102), whereby the movable portion 134a is moved away from the relatively stationary frame portion 136. In a second state, the bi-metallic disc actuator 134 is concave relative to the relatively stationary frame portion 136, whereby the movable portion 134a is moved toward the relatively stationary frame portion 136.

One of the cooperating electrical switch contacts 116 (or 118) is formed on the relatively movable portion 134a of the thermally-responsive actuator 134 opposite from the other cooperating electrical switch contact 118 (or 116) formed on the relatively stationary frame portion 136 with the two switch contacts 116, 118 being mutually electrically isolated, for example, by the insulator 110.

As a function of sensed ambient temperature and whether the contacts 116, 118 are normally closed or normally open (shown), the thermally-responsive actuator 134 exerts an internal force Fc that drives the movable portion 134a toward the relatively stationary frame portion 136, whereby the cooperating electrical switch contacts 116, 118 are driven together such that they form a closed circuit. A change in sensed ambient temperature generates a opposite internal force Fo that drives the movable portion 134a away from the relatively stationary frame portion 136, whereby the cooperating electrical switch contacts 116, 118 are driven apart such that they form an open circuit.

The substrate 104 (or 102) forming the relatively stationary frame portion 136 is optionally an insulator, as illustrated, having the electrically conductive electrode layer 108 (or 106) applied to one of its surfaces. Alternatively, the substrate 104 (or 102) forming the relatively stationary frame portion 136 is an electrical conductor formed of any of a metal, a semiconductor, or a conductive oxide, whereby the electrically conductive electrode layer 108 (or 106) is eliminated.

While the preferred embodiment of the invention has been illustrated and described, it will be appreciated that various changes can be made therein without departing from the spirit and scope of the invention.

What is claimed is:

1: A micromachined mechanical switch device, comprising:
first and second spaced apart electrical conductors formed with respective first and second opposing substantially planar electrically conductive contact surfaces, the first electrical conductor being movable relative to the second electrical conductor; and
first and second cooperating electrical switch contacts formed on the respective first and second opposing electrically conductive contact surfaces, the first and second cooperating electrical switch contacts comprising respective first and second patterns of carbon nanotube thin film structures adhered to the respective first and second electrically conductive contact surfaces.

2: The device of claim 1 wherein one or more of the first and second electrical conductors further comprises a substrate formed with the respective first and second opposing substantially planar electrically conductive contact surfaces.

3: The device of claim 2 wherein the substrate further comprises a first portion that is movable relative to a second portion, the first portion having the first electrical switch contact formed thereon, and the second portion being substantially stationary relative to the second electrical conductor and spaced apart therefrom.

4: The device of claim 3 wherein the substrate further comprises a thermally-responsive actuator having the first portion that is movable relative to the second portion.

5: The device of claim 4 wherein the substrate further comprises a bi-metallic substrate that is responsive to a change in sensed temperature for changing between two bi-stable oppositely concave and convex states.

6: The device of claim 1 wherein the first and second electrical conductors are further spaced apart by an insulator.

7: The device of claim 1 wherein one or more of the first and second carbon nanotube thin film structures further comprises first and second patterns of a patterning material combined with respective first and second quantities of carbon nanotubes, wherein the patterning material is selected from (a) carbon-dissolving materials, (b) carbide-forming materials, and (c) metals having a melting point of about 700 degrees C. or less.

8: A micromachined mechanical switch device, comprising:
first and second spaced apart electrical conductors, the first electrical conductor further comprising a stationary portion thereof that is substantially stationary relative to the second electrical conductor and a movable portion thereof that is movable relative to the stationary portion and is further movable toward and away from contact with the second electrical conductor;
a first pattern of carbon nanotubes forming a first electrical switch contact on the movable portion of the first electrical conductor;
a second pattern of carbon nanotubes forming a second electrical switch contact on the second electrical conductor opposite from the first electrical switch contact; and
wherein the movable portion of the first electrical conductor is further operable for electrically coupling and de-coupling the first and second electrical switch contacts.

9: The device of claim 8 wherein the first and second electrical conductors further comprise respective first and second substantially planar substrates that are formed of a material that is substantially non-reactive with carbon and has a melting point of at least 1000 degrees C.

10: The device of claim 9 wherein the first and second electrical conductors further comprise respective first and second substrates that are formed with respective first and second opposing substantially planar electrically conductive contact surfaces having the respective first and second patterns of carbon nanotubes formed thereon.

11: The device of claim 10 wherein each of the first and second electrical switch contacts further comprises a patterning material deposited onto the respective first and second electrically conductive contact surfaces and having the carbon nanotubes combined therewith, the patterning material being selected from the group of patterning materials consisting of (a) carbon-dissolving materials, (b) carbide-forming materials, and (c) metals having a melting point of about 700 degrees C. or less.

12: The device of claim 11 wherein the first substrate further comprises one or more flexures between the movable and stationary portions.

13: The device of claim 12 wherein one of the first and second substrates further comprises a thermally-responsive snap-action bi-metallic strip operable between two bi-stable oppositely concave and convex states.

14: A method for forming first and second cooperating electrical switch contacts, the method comprising.
depositing patterning material onto first and second opposing substantially planar electrically conductive contact surfaces of respective first and second substrates; and
depositing respective first and second patterns of carbon nanotube thin film structures adhered to the respective first and second electrically conductive contact surfaces.

15: The method of claim 14, wherein depositing one or more of the first and second carbon nanotube thin film structures farther comprises locally depositing the carbon nanotube thin film structures by positioning a shadow mask adjacent to the respective first and second substrates and exposing the first and second electrically conductive contact surfaces through a pattern of openings through the shadow mask, and depositing one or more of the first and second carbon nanotube thin film structures through the pattern of openings in the shadow mask.

16: The method of claim 14 wherein depositing one or more of the first and second carbon nanotube thin film structures further comprises depositing a layer of sacrificial material in a pattern on the respective first and second substrates exclusive of the first and second electrically conductive contact surfaces, blanket depositing a layer of carbon nanotubes over the layer of sacrificial material and contact surfaces, and removing both the layer of sacrificial material and the carbon nanotubes deposited thereon.

17: The method of claim 14, further comprising fabricating a micromachined mechanical switch device by positioning the first and second electrical conductors in relatively opposing and spaced apart state.

18: The method of claim 17 wherein the first substrate further comprises a first portion that is movable relative to a second portion, the first portion having the first electrical switch contact formed thereon, and the second portion being substantially stationary relative to the second electrical contact and spaced apart therefrom; and
further comprising positioning the first and second electrical contacts with the first electrical conductor being movable relative to the second electrical conductor between the first state wherein the electrical conductors are relatively opposing and spaced apart, and a second state wherein the first electrical switch contact is positioned in electrically conductive contact with the second electrical contact.

19: The method of claim 18 wherein the relatively movable portion of the first substrate further comprises a thermally-responsive actuator having the first electrical switch contact formed thereon, and the second portion being substantially stationary relative to the second electrical contact and spaced apart therefrom.

20: The method of claim 19 wherein the first substrate further comprises a bi-metallic substrate that is responsive to a change in sensed temperature for changing between two bi-stable oppositely concave and convex states.
